(19) United States
(12) Patent Application Publication
(10) Pub. No.: US 2026/0361449 A1
(43) Pub. Date: Nov. 12, 2026

(54) FROZEN BIT SELECTION AND INDICATION FOR POLAR CODING SCHEME

(71) Applicant: QUALCOMM Incorporated, San Diego, CA (US)

(72) Inventors: Peer BERGER, Hod Hasharon (IL); Jacob PICK, Mevaseret Zion (IL); Shay LANDIS, Hod Hasharon (IL)

(21) Appl. No.: 19/202,378

(22) Filed: May 8, 2025

(51) Int. Cl. H04L 1/00; H04L 1/20; H04L 5/00

(52) U.S. Cl. CPC H04L 1/001; H04L 1/0002; H04L 1/203; H04L 5/0053

(57) ABSTRACT

Various aspects of the present disclosure generally relate to wireless communication. In some aspects, a user equipment (UE) may receive, from a network node, a first message in accordance with a polar coding scheme. The UE may transmit, to the network node, an indication of one or more frozen bits associated with the polar coding scheme, wherein the one or more frozen bits are selected in accordance with the first message. The UE may receive, from the network node, a second message in accordance with the one or more frozen bits. Numerous other aspects are described.

### FIELD OF THE DISCLOSURE

Aspects of the present disclosure generally relate to wireless communication and specifically relate to techniques, apparatuses, and methods associated with frozen bit selection and indication for polar coding schemes.

### DESCRIPTION OF THE RELATED TECHNOLOGY

Wireless communication systems are widely deployed to provide various services, which may involve carrying or supporting voice, text, other messaging, video, data, or other traffic. Typical wireless communication systems may employ multiple-access radio access technologies (RATs) capable of supporting communication among multiple wireless communication devices including user devices or other devices by sharing the available system resources (for example, time domain resources, frequency domain resources, spatial domain resources, or device transmit power, among other examples). Such multiple-access RATs are supported by technological advancements that have been adopted in various telecommunication standards, which define common protocols that enable different wireless communication devices to communicate on a local, municipal, national, regional, or global level. An example telecommunication standard is New Radio (NR). NR, which also may be referred to as 5G, is part of a continuous mobile broadband evolution promulgated by the Third Generation Partnership Project (3GPP). As the demand for connectivity continues to increase, further improvements in NR may be implemented, and other RATs, such as 6G and beyond, may be introduced to enable new applications and facilitate new use cases.

In a wireless communication system, information is generally represented as a sequence of binary bits that are mapped (for example, modulated) to an analog signal waveform that is then transmitted to a receiver over a wireless communication channel. In some cases, however, the wireless communication channel may introduce errors that may corrupt the transmitted signal due to random noise, interference, device impairments, or other factors. At the receiver, the received signal (that may have been corrupted during transmission) is mapped back to binary bits, with the received binary information estimating the transmitted binary information. Accordingly, because errors may corrupt the signal that is estimated at the receiver, channel coding or forward error correction (FEC) techniques are often used to control errors in data transmission over unreliable or noisy communication channels, or otherwise mitigate the bit errors that may occur due to noise, interference, or other factors. For example, channel coding generally includes an encoding operation performed at a transmitter (for example, a first wireless device, which may be a user equipment (UE) or a network node) and a decoding operation performed at a receiver (for example, a second wireless device, which may be a UE or a network node). Channel coding is generally accomplished by selectively introducing redundancy into the transmitted information stream, typically using an error correction code (ECC), which allows the receiver to detect errors or correct bit errors in the received data stream and thereby provide more reliable information transmission. Accordingly, channel codes are often used in scenarios where retransmissions are undesirable or high transmission reliability is needed, such as downlink or uplink control channel communications.

For example, a wireless network may use polar codes to implement channel coding for downlink or uplink control channel communications. M ore particularly, polar coding is a linear block coding technique that has provable capacity-achieving performance over binary channels with polynomial complexity in various scenarios (such as channel coding, among others). Polar coding has a built-in channel polarization structure that uses a recursive construction to split (or “polarize”) a communication channel into reliable subchannels that are very good for transmitting information and unreliable subchannels that are very bad for transmitting information. The reliable subchannels may be almost completely noiseless, with a capacity that approaches 1, and the unreliable subchannels may be almost completely noisy, with a capacity that approaches 0. During polar encoding, a polar transform is applied to assign information bits to the reliable subchannels and to assign “frozen” or “fixed” bits (for example, “0” bits) to the unreliable subchannels.

### SUMMARY

The systems, methods, and devices of this disclosure each have several innovative aspects, no single one of which is solely responsible for the desirable attributes disclosed herein.

Some aspects described herein relate to a user equipment (UE). The UE may include a processing system. The processing system may include one or more processors and one or more code-storing memories coupled with the one or more processors. The processing system may be configured to cause the UE to receive, from a network node, a first message in accordance with a polar coding scheme. The processing system may be configured to cause the UE to transmit, to the network node, an indication of one or more frozen bits associated with the polar coding scheme, wherein the one or more frozen bits are selected in accordance with the first message. The processing system may be configured to cause the UE to receive, from the network node, a second message in accordance with the one or more frozen bits.

Some aspects described herein relate to a network node. The network node may include a processing system. The processing system may include one or more processors and one or more code-storing memories coupled with the one or more processors. The processing system may be configured to cause the network node to transmit, to a UE, a first message in accordance with a polar coding scheme. The processing system may be configured to cause the network node to receive, from the UE, an indication of one or more frozen bits associated with the polar coding scheme, wherein the one or more frozen bits are selected in accordance with the first message. The processing system may be configured to cause the network node to transmit, to the UE, a second message in accordance with the one or more frozen bits.

Some aspects described herein relate to a method of wireless communication performed by a UE. The method may include receiving, from a network node, a first message in accordance with a polar coding scheme. The method may include transmitting, to the network node, an indication of one or more frozen bits associated with the polar coding scheme, wherein the one or more frozen bits are selected in accordance with the first message. The method may include receiving, from the network node, a second message in accordance with the one or more frozen bits.

Some aspects described herein relate to a method of wireless communication performed by a network node. The method may include transmitting, to a UE, a first message in accordance with a polar coding scheme. The method may include receiving, from the UE, an indication of one or more frozen bits associated with the polar coding scheme, wherein the one or more frozen bits are selected in accordance with the first message. The method may include transmitting, to the UE, a second message in accordance with the one or more frozen bits.

Some aspects described herein relate to a non-transitory computer-readable medium that stores a set of instructions for wireless communication by a UE. The set of instructions, when executed by one or more processors of the UE, may cause the UE to receive, from a network node, a first message in accordance with a polar coding scheme. The set of instructions, when executed by one or more processors of the UE, may cause the UE to transmit, to the network node, an indication of one or more frozen bits associated with the polar coding scheme, wherein the one or more frozen bits are selected in accordance with the first message. The set of instructions, when executed by one or more processors of the UE, may cause the UE to receive, from the network node, a second message in accordance with the one or more frozen bits.

Some aspects described herein relate to a non-transitory computer-readable medium that stores a set of instructions for wireless communication by a network node. The set of instructions, when executed by one or more processors of the network node, may cause the network node to transmit, to a UE, a first message in accordance with a polar coding scheme. The set of instructions, when executed by one or more processors of the network node, may cause the network node to receive, from the UE, an indication of one or more frozen bits associated with the polar coding scheme, wherein the one or more frozen bits are selected in accordance with the first message. The set of instructions, when executed by one or more processors of the network node, may cause the network node to transmit, to the UE, a second message in accordance with the one or more frozen bits.

Some aspects described herein relate to an apparatus for wireless communication. The apparatus may include means for receiving, from a network node, a first message in accordance with a polar coding scheme. The apparatus may include means for transmitting, to the network node, an indication of one or more frozen bits associated with the polar coding scheme, wherein the one or more frozen bits are selected in accordance with the first message. The apparatus may include means for receiving, from the network node, a second message in accordance with the one or more frozen bits.

Some aspects described herein relate to an apparatus for wireless communication. The apparatus may include means for transmitting, to a UE, a first message in accordance with a polar coding scheme. The apparatus may include means for receiving, from the UE, an indication of one or more frozen bits associated with the polar coding scheme, wherein the one or more frozen bits are selected in accordance with the first message. The apparatus may include means for transmitting, to the UE, a second message in accordance with the one or more frozen bits.

Aspects of the present disclosure may generally be implemented by or as a method, apparatus, system, computer program product, non-transitory computer-readable medium, user equipment, network node, wireless communication device, or processing system as substantially described in the Detailed Description with reference to, and as illustrated by, the accompanying drawings. Details of one or more implementations of the subject matter described in this disclosure are set forth in the accompanying drawings and the description below. Other features, aspects, and advantages will become apparent from the description, the drawings, and the claims. Note that the relative dimensions of the following FIGURES may not be drawn to scale.

### BRIEF DESCRIPTION OF THE DRAWINGS

FIG. 1 is a diagram illustrating an example of a wireless communication network.

FIG. 2 is a diagram illustrating an example of a polar encoding operation in accordance with the present disclosure.

FIG. 3 is a diagram illustrating an example associated with frozen bit selection for polar coding schemes.

FIG. 4 is a diagram illustrating an example associated with frozen bit selection for polar coding schemes.

FIG. 5 is a diagram illustrating an example process performed, for example, at a user equipment (UE) or an apparatus of a UE.

FIG. 6 is a diagram illustrating an example process performed, for example, at a network node or an apparatus of a network node.

FIG. 7 is a diagram of an example apparatus for wireless communication.

FIG. 8 is a diagram of an example apparatus for wireless communication.

### DETAILED DESCRIPTION

In some wireless communication systems, polar codes may be used for channel encoding for downlink or uplink control channel communications. Polar codes may utilize “frozen bits,” which are input bits fixed to known values for both the encoder and decoder to ensure successful transmission. For example, polar coding involves polarizing a communication channel into reliable subchannels (e.g., having a symmetric capacity that approaches 1, which may correspond to a noiseless channel) and unreliable subchannels (e.g., having a symmetric capacity that approaches 0, which may correspond to a pure noise channel). Typically, frozen bits may be assigned to the unreliable subchannels and information bits may be assigned to the reliable subchannels. Accordingly, the selection of frozen bits is important for effective encoding, as suboptimal selection can cause information bits to be assigned to unreliable subchannels, which may significantly degrade channel performance.

The process of frozen bit selection may be influenced by numerous factors, including the coding scheme used, a constellation, bit labeling, and decoding methods used. Additionally, channel conditions may have a significant impact on frozen bits selection. For example, when channel conditions (e.g., Doppler spread, signal-to-noise ratio (SNR), or other conditions) change, the previously-selected frozen bits may be suboptimal, leading to channel degradation. Accordingly, updating frozen bits while in an online setting may be beneficial, to adjust the frozen bits to changing channel conditions.

In some wireless communication systems, the selection of frozen bits is performed offline using methods like Monte Carlo simulation, which may involve estimating a bit error rate (BER) based on each bit position by transmitting multiple known-data transmissions and forcing correct previous decisions to eliminate error propagation, where the BER corresponds to a quantity of bit errors divided by a total number of bits. Frozen bits may then be indicated or configured to devices of the wireless communication systems for use in channel coding. However, these methods may require a substantial amount of known data to be transmitted in order to achieve an accurate estimation, and the methods may therefore be impractical for online frozen bit estimation due to the time and overhead constraints associated with achieving accurate results. For example, as Monte Carlo simulations require knowledge of the transmitted data, implementing online Monte Carlo simulations may involve a large number of transmissions between a network node and a user equipment (UE), resulting in significant overhead, time constraints, and power consumption.

Various aspects relate generally to the selection of frozen bits for polar coding schemes. Some aspects more specifically relate to enabling a UE to estimate frozen bits and indicate the frozen bits dynamically (e.g., in an online setting) to a network node for use in communications. The UE may receive a downlink message from a network node encoded using a default set of frozen bits (e.g., specified in the standard or based on offline estimation). In some aspects, the UE may be configured to estimate a BER from a decoder output in accordance with the reception of the message (e.g., the decoder output from processing of the downlink message). For example, the UE may estimate the BER using one or more log-likelihood ratios (LLRs) associated with the downlink message, such as using code blocks that have passed a cyclic redundancy check (CRC), where the CRC may involve checking a fixed-size check value that is appended to data. In some aspects, the UE may estimate the BER using LLRs at a soft decoder output for all bits of code blocks that have passed the CRC, including frozen bits and information bits, and the UE may be configured to discard code blocks that did not pass the CRC. Accordingly, the UE may be configured to select frozen bits in accordance with the estimated BER, and the selected frozen bits may be different from the default set of frozen bits. In some aspects, the UE may be configured to transmit, to the network node, an indication of the selected frozen bits. For example, the UE may transmit a report that includes a table of bit indexes that indicates which bits are frozen bits or information bits, or the UE may transmit a request to freeze or unfreeze specific bits (e.g., relative to the set of default bits). Additionally, or alternatively, the UE may transmit an indication of one or more estimated BERs for one or more bits (e.g., for selected frozen bits, information bits, or a combination thereof). In some aspects, the network node may transmit subsequent messages to the UE in accordance with the updated frozen bits based on the indication of the frozen bits transmitted by the UE. Additionally, or alternatively, the network node may select frozen bits for uplink messages transmitted by the UE based on the indication of the frozen bits or the indication of the one or more estimated BERs. In some aspects, the network node may transmit, to the UE, an indication of the updated frozen bits for uplink or downlink communications.

Particular aspects of the subject matter described in this disclosure can be implemented to realize one or more of the following potential advantages. By enabling the UE to estimate and report updated frozen bits dynamically, the described techniques may improve communication performance in varying channel conditions. For example, by the UE estimating a BER and selecting frozen bits in an online setting, frozen bits may be updated without using extensive offline simulations and known data transmissions, thereby improving polar coding performance when in channels with varying conditions, relative to using a fixed set of frozen bits. Additionally, the use of an LLR at an output of the soft decoder for BER estimation allows a UE to estimate frozen bits using components that the UE may already be equipped with for performing wireless communications, thereby allowing for existing UEs to support frozen bit estimation and reporting. Accordingly, this dynamic approach to frozen bit selection improves channel performance in wireless communication systems, even in changing wireless environments, which may lead to the conservation of processing resources, memory resources, or network resources by reducing the need for repeated transmissions or extensive channel simulations.

5G New Radio (NR) may support enhanced mobile broadband (eMBB) access, Internet of Things (IoT) networks or reduced capability (RedCap) device deployments, ultra-reliable low-latency communication (URLLC) applications, or massive machine-type communication (mMTC), among other examples. To support these and other target verticals, a wireless communication system may be designed to implement a modularized functional infrastructure, a disaggregated and service-based network architecture, network function virtualization, network slicing, multi-access edge computing, millimeter wave (mmWave) technologies including massive multiple-input multiple-output (MIMO), beamforming, IoT device or RedCap device connectivity and management, industrial connectivity, licensed and unlicensed spectrum access, sidelink and other device-to-device direct communication (for example, cellular vehicle-to-everything (CV2X) communication), frequency spectrum expansion, overlapping spectrum use, small cell deployments, non-terrestrial network (NTN) deployments, device aggregation, advanced duplex communication (for example, sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases, such as wireless fronthauls, wireless midhauls, wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial or aerial platforms, among other examples.

The methods, operations, apparatuses, and techniques described herein may enable one or more of the foregoing technologies or new technologies or support one or more of the foregoing use cases or new use cases.

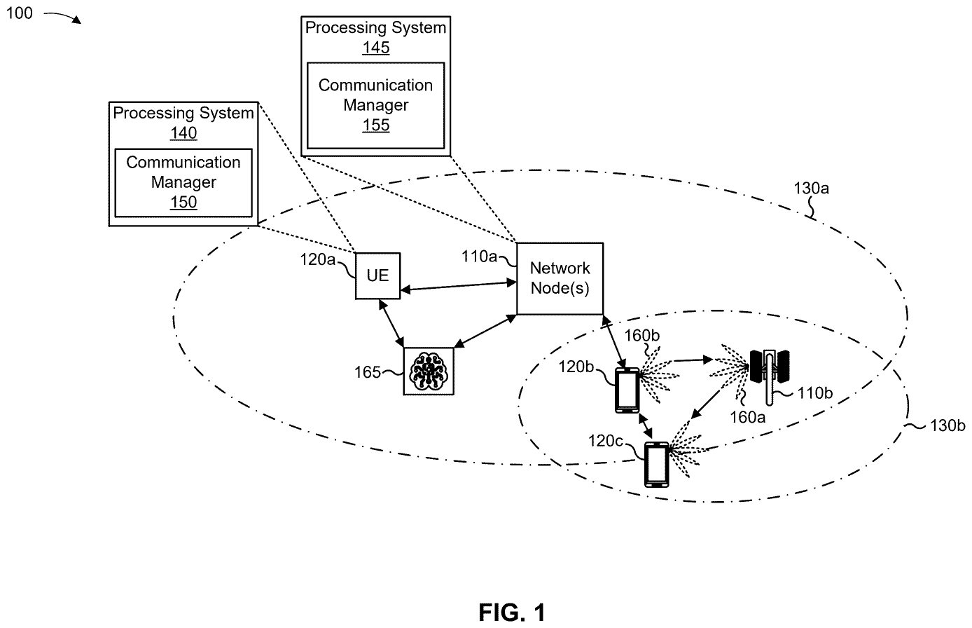

FIG. 1 is a diagram illustrating an example of a wireless communication network 100. The wireless communication network 100 may be or may include elements of a 5G network or a 6G network, among other examples. The wireless communication network 100 may include multiple network nodes 110. For example, in FIG. 1, the wireless communication network 100 includes multiple network nodes 110, including a network node 110a and a network node 110b (each of which also may be referred to herein simply as a “network node 110”). The network nodes 110 may support communications with multiple UEs 120. For example, in FIG. 1, the network nodes 110 support communication with a UE 120a, a UE 120b, and a UE 120c (each of which also may be referred to herein simply as a “UE 120”). In some examples, a UE 120 also may communicate with other UEs 120 and a network node 110 also may communicate with a core network and with other network nodes 110.

The network nodes 110 and the UEs 120 of the wireless communication network 100 communicate using the electromagnetic spectrum, which may be subdivided into various licensed or unlicensed operating bands, frequency ranges, component carriers, or channels that define associated frequencies available for communications. In some examples, each of the network nodes 110 and the UEs 120 may communicate using one or multiple component carriers in one or more operating bands or ranges. Typically, various operating bands are defined as frequency range designations FR1 (410 Megahertz (M Hz) through 7.125 Gigahertz (GHz)), FR2 (24.25 GHz through 52.6 GHz), FR3 (7.125 GHz through 24.25 GHz), FR4a or FR4-1 (52.6 GHz through 71 GHz), FR4 (52.6 GHz through 114.25 GHZ), and FR5 (114.25 GHZ through 300 GHz). Although a portion of FR1 is greater than 6 GHZ, FR1 is often referred to (interchangeably) as a “sub-6 GHz” band in some documents and articles. Similarly, FR2 is often referred to (interchangeably) as a “millimeter wave” band in some documents and articles.

A network node 110 or a UE 120 may include one or more devices, components, or systems that enable communication with other devices, components, or systems of the wireless communication network 100. For example, a UE 120 and a network node 110 may each include one or more chips, system-on-chips (SoCs), chipsets, packages, or devices that individually or collectively constitute or comprise a processing system. As shown in FIG. 1, each UE 120 includes a processing system 140 and each network node 110 includes a processing system 145. A processing system (for example, the processing system 140 or the processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set. In some other examples, each of a group of processors may be configurable or configured to perform a same set of functions.

The processing system 140 and the processing system 145 may each include memory circuitry in the form of one or multiple memory devices, memory blocks, memory elements, or other discrete gate or transistor logic or circuitry, each of which may include or implement tangible storage media, such as random-access memory, or read-only memory, or combinations thereof (any one or more of which may be generally referred to herein individually as a “memory” or collectively as “the memory” or “the memory circuitry”). One or more of the memories may be coupled (for example, operatively coupled, communicatively coupled, electronically coupled, or electrically coupled) with one or more of the processors. One or more of the memories may individually or collectively store processor-executable code or instructions (such as software) (for example, which may be referred to as “one or more code-storing memories” or “code-storing memory circuitry”). For example, “code-storing memory” or “code-storing memory circuitry” refers to memory (or memory circuitry) that is configured to store processor-executable code or instructions. The processor-executable code or instructions, when executed by one or more of the processors, may configure one or more of the processors (or processing circuitry) to perform various functions or operations described herein. Additionally, or alternatively, in some examples, one or more of the processors may be configured to perform various functions or operations described herein without requiring configuration by software. Software shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

The processing system 140 and the processing system 145 may each include or be coupled with one or more modems (such as a cellular (for example, a 5G or 6G compliant) modem). In some examples, one or more processors of the processing system 140 or the processing system 145 may include or implement one or more of the modems. The processing system 140 and the processing system 145 also may include or be coupled with multiple radios (collectively “the radio”), multiple RF chains, or multiple transceivers, each of which may in turn be coupled with one or more of multiple antennas. In some examples, one or more processors of the processing system 140 or the processing system 145 may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by the processing system 140 or by the processing system 145).

A network node 110 and a UE 120 may each include one or multiple antennas or antenna arrays. Typical network nodes 110 and UEs 120 may include multiple antennas, which may be organized or structured into one or more antenna panels, one or more antenna groups, one or more sets of antenna elements, or one or more antenna arrays, among other examples. As used herein, the term “antenna” can refer to one or more antennas, one or more antenna panels, one or more antenna groups, one or more sets of antenna elements, or one or more antenna arrays. The term “antenna panel” can refer to a group of antennas (such as antenna elements) arranged in an array or panel, which may facilitate beamforming by manipulating parameters associated with the group of antennas. The term “antenna module” may refer to circuitry including one or more antennas as well as one or more other components (such as filters, amplifiers, or processors) associated with integrating the antenna module into a wireless communication device, such as the network node 110 and the UE 120.

A network node 110 may be, may include, or also may be referred to as an NR network node, a 5G network node, a 6G network node, a Node B, a gNB, an access point (AP), a transmission reception point (TRP), a network entity, a network element, a network equipment, or another type of device, component, or system included in a radio access network (RAN). In various deployments, a network node 110 may be implemented as a single physical node (for example, a single physical structure) or may be implemented as two or more physical nodes (for example, two or more distinct physical structures). For example, a network node 110 may be a device or system that implements a part of a radio protocol stack, a device or system that implements a full radio protocol stack (such as a full gNB protocol stack), or a collection of devices or systems that collectively implement the full radio protocol stack. For example, and as shown, a network node 110 may be an aggregated network node having an aggregated architecture, meaning that the network node 110 may implement a full radio protocol stack that is physically and logically integrated within a single physical structure in the wireless communication network 100. For example, an aggregated network node 110 may include a single standalone base station or a single TRP that operates with a full radio protocol stack to enable or facilitate communication between a UE 120 and a core network of the wireless communication network 100.

Alternatively, a network node 110 may be a disaggregated network node 110 (sometimes referred to as a disaggregated base station), having a disaggregated architecture, meaning that the network node 110 may operate with a radio protocol stack that is physically distributed or logically distributed among two or more nodes in the same geographic location or in different geographic locations. In some deployments, disaggregated network nodes 110 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating network functionality into multiple units or modules that can be individually deployed.

The disaggregated network nodes 110 of the wireless communication network 100 may include one or more central units (CUs), one or more distributed units (DUs), and one or more radio units (RUs). A CU may host one or more higher layers, such as a radio resource control (RRC) layer, a packet data convergence protocol (PDCP) layer, and a service data adaptation protocol (SDAP) layer, among other examples. A CU can communicate with a core network either directly (for example, via a backhaul link) or indirectly (for example, via one or more disaggregated control units, such as a non-real-time (Non-RT) RAN intelligent controller (RIC) associated with a Service Management and Orchestration (SMO) framework or a near-real-time (Near-RT) RIC). A DU may host one or more of a radio link control (RLC) layer, a medium access control (MAC) layer, or one or more higher physical (PHY) layers depending, at least in part, on a functional split, such as a functional split defined by the 3GPP. In some examples, a DU also may host a lower PHY layer that is configured to perform functions, such as a fast Fourier transform (FFT), an inverse FFT (IFFT), beamforming, or physical random access channel (PRACH) extraction and filtering, among other examples. An RU may perform RF processing functions or lower PHY layer functions, such as an FFT, an IFFT, beamforming, or PRACH extraction and filtering, among other examples, according to a functional split, such as a lower layer split (LLS). In such an architecture, each RU can be operated to handle over the air (OTA) communication with one or more UEs 120. A CU may communicate with one or more DUs via respective midhaul links, such as via F1 interfaces. Each of the DUs may communicate with one or more RUs via respective fronthaul links. Each of the RUs may communicate with one or more UEs 120 via respective RF access links. In some deployments, a UE 120 may be simultaneously served by multiple RUs.

In some examples, a single network node 110 may include a combination of one or more CUs, one or more DUs, or one or more RUs. In some examples, a CU, a DU, or an RU may be implemented as a virtual unit, such as a virtual central unit (VCU), a virtual distributed unit (VDU), or a virtual radio unit (VRU), among other examples, which may be implemented as a virtual network function, such as in a cloud deployment (for example, an open cloud (O-Cloud) platform). An SMO framework may support RAN deployment and provisioning of non-virtualized and virtualized network elements.

In some examples, the wireless communication network 100 may be a heterogeneous network that includes network nodes 110 of various types. Different types of network nodes 110 may generally operate on the same or different operating bands, transmit at different power levels, or serve different coverage areas, each of which may be referred to as or associated with a particular cell 130 (for example, a cell 130a and a cell 130b).

The UEs 120 may be physically dispersed throughout the coverage area of the wireless communication network 100, and each UE 120 may be stationary or mobile. A UE 120 may be, may include, or also may be referred to as an access terminal, a mobile station, a client device, or a subscriber unit. A UE 120 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a netbook, a smartbook, an ultrabook, a medical device, a biometric device, a wearable device (for example, a smart watch, smart clothing, smart glasses, a smart wristband, or smart jewelry), a gaming device, an entertainment device (for example, a music device, a video device, or a satellite radio), an XR device, a vehicular component or sensor, a smart meter or sensor, industrial manufacturing equipment, a Global Navigation Satellite System (GNSS) device (such as a Global Positioning System device or another type of positioning device), an artificially intelligent robot or other device implementing artificial intelligence, a UE function of a network node, or any other suitable device or function that may communicate in the wireless communication network 100.

Some UEs 120 may be classified according to different categories in association with different complexities or different capabilities. UEs 120 in a first category may be associated with relatively low complexity or cost such as NB-IoT devices or eMTC UEs. UEs 120 in a second category may include higher complexity or cost devices, such as mission-critical IoT devices, baseline UEs, high-tier UEs, advanced UEs, full-capability UEs, or premium UEs that are capable of URLLC, eMBB, or precise positioning in the wireless communication network 100. A third category of UEs 120 may have mid-tier complexity or capabilities (for example, capabilities between that of the UEs 120 of the first category and the UEs 120 of the second category). A UE 120 of the third category may be referred to as a reduced capability UE (“RedCap UE”), a mid-tier UE, an NR-Light UE, or an NR-Lite UE, among other examples.

In some examples, a network node 110 may be, may include, or may operate as an RU, a TRP, or a base station that communicates with one or more UEs 120 via a radio access link (which may be referred to as a “Uu” link). The radio access link may include a downlink and an uplink. “Downlink” (or “DL”) refers to a communication direction from a network node 110 to a UE 120, and “uplink” (or “UL”) refers to a communication direction from a UE 120 to a network node 110. Downlink and uplink resources may include time domain resources (for example, frames, subframes, slots, and symbols), frequency domain resources (for example, frequency bands, component carriers (CCs), subcarriers, resource blocks, and resource elements), and spatial domain resources (for example, particular transmit directions or beams).

Frequency domain resources may be subdivided into bandwidth parts (BWPs). A BWP may be a block of frequency domain resources (for example, a continuous set of resource blocks (RBs) within a full component carrier bandwidth) that may be configured at a UE-specific level. A UE 120 may be configured with both an uplink BWP and a downlink BWP (which may be the same or different). Each BWP may be associated with its own numerology (indicating a sub-carrier spacing (SCS) and cyclic prefix (CP)). A BWP may be dynamically configured or activated (for example, by a network node 110 transmitting a downlink control information (DCI) configuration to the one or more UEs 120) or reconfigured (for example, in real-time or near-real-time) according to changing network conditions in the wireless communication network 100 or specific requirements of one or more UEs 120. An active BWP defines the operating bandwidth of the UE 120 within the operating bandwidth of the serving cell.

As used herein, a downlink signal may be or include a reference signal, control information, or data. For example, downlink reference signals include a primary synchronization signal (PSS), a secondary SS (SSS), an SS block (SSB) (for example, that includes a PSS, an SSS, and a physical broadcast channel (PB CH)), a demodulation reference signal (DMRS), a phase tracking reference signal (PTRS), a tracking reference signal (TRS), and a channel state information (CSI) reference signal (CSI-RS), among other examples. A downlink signal carrying control information or data may be transmitted via a downlink channel. Downlink channels may include one or more control channels for transmitting control information and one or more data channels for transmitting data. Downlink reference signals may be transmitted in addition to, or multiplexed with, downlink control channel communications or downlink data channel communications. A downlink control channel may be specifically used to transmit DCI from a network node 110 to a UE 120. DCI generally contains the information the UE 120 needs to identify RBs in a subsequent subframe and how to decode them, including a modulation and coding scheme (MCS) or redundancy version parameters. Different DCI formats carry different information, such as scheduling information in the form of downlink or uplink grants, slot format indicators (SFIs), preemption indicators (PIs), transmit power control (TPC) commands, hybrid automatic repeat request (HARQ) information, new data indicators (NDIs), among other examples. A downlink data channel may be used to transmit downlink data (for example, user data associated with a UE 120) from a network node 110 to a UE 120. Downlink control channels may include physical downlink control channels (PDCCHs), and downlink data channels may include physical downlink shared channels (PDSCHs). Control information or data communications may be transmitted on a PDCCH and PDSCH, respectively. For example, a PDCCH can carry DCI, while a PDSCH can carry a MAC control element (MAC-CE), an RRC message, or user data, among other examples. Each PDSCH may carry one or more transport blocks (TBs) of data.

As used herein, an uplink signal may include a reference signal, control information, or data. For example, uplink reference signals include a sounding reference signal (SRS), a PTRS, and a DMRS, among other examples. An uplink signal carrying control information or data may be transmitted via an uplink channel. An uplink channel may include one or more control channels for transmitting control information and one or more data channels for transmitting data. U plink reference signals may be transmitted in addition to, or multiplexed with, uplink control channel communications or uplink data channel communications. An uplink control channel may be specifically used to transmit uplink control information (UCI) from a UE 120 to a network node 110. An uplink data channel may be used to transmit uplink data (for example, user data associated with a UE 120) from a UE 120 to a network node 110. U plink control channels may include physical uplink control channels (PUCCHs), and uplink data channels may include physical uplink shared channels (PUSCHs). Control information or data communications may be transmitted on a PUCCH and PUSCH, respectively. For example, a PUCCH can carry UCI, while a PUSCH can carry a MAC-CE, an RRC message, or user data, among other examples. UCI can include a scheduling request (SR), HARQ feedback information (for example, a HARQ acknowledgement (ACK) indication or a HARQ negative acknowledgement (NACK) indication), uplink power control information (for example, an uplink TPC parameter), or CSI, among other examples. CSI can include a channel quality indicator (CQI) (indicative of downlink channel conditions to facilitate selection of transmission parameters, such as an MCS, by a network node 110), a precoding matrix indicator (PMI), a CSI-RS resource indicator (CRI) (for example, indicative of a beam used to transmit a CSI-RS), an SS/PBCH resource block indicator (SSBRI) (for example, indicative of a beam used to transmit an SSB), a layer indicator (LI), a rank indicator (RI), or measurement information (for example, a layer 1 (L1)-reference signal received power (RSRP) parameter, a received signal strength indicator (RSSI) parameter, a reference signal received quality (RSRQ) parameter, among other examples) which can be used for beam management, among other examples. Each PUSCH may carry one or more TBs of data.

The information (for example, data, control information, or reference signal information) transmitted by a network node 110 to a UE 120, or vice versa, may be represented as a sequence of binary bits that are mapped (for example, modulated) to an analog signal waveform (for example, a discrete Fourier transform (DFT)-spread-orthogonal frequency division multiplexing (OFDM) (DFT-s-OFDM) waveform or a CP-OFDM waveform) that is transmitted by the network node 110 or UE 120 over a wireless communication channel. In some examples, the network node 110 or the UE 120 (for example, using the processing system 145 or the processing system 140, respectively) may select an MCS (for example, an order of quadrature amplitude modulation (QAM), such as 64-QAM, 128-QAM, or 256-QAM, among other examples) for a downlink signal or an uplink signal. For example, the network node 110 may select an MCS for a downlink signal in accordance with UCI received from the UE 120 or may transmit, to the UE 120, an indication of an MCS to be applied for an uplink signal.

A network node 110 or a UE 120 (such as by using the processing system 145 or the processing system 140, respectively, or one or more coupled modems) may perform signal processing on the information (such as filtering, amplification, modulation, digital-to-analog conversion, an IFFT operation, multiplexing, interleaving, mapping, or encoding, among other examples) to generate a processed signal in accordance with the selected MCS. In some examples, the network node 110 or the UE 120 (for example, using the processing system 145 or the processing system 140, respectively, or one or more coupled encoders or modems) may perform a channel coding operation or a forward error correction (FEC) operation to control errors in transmitted information. For example, the network node 110 or the UE 120 may perform an encoding operation to generate encoded information (such as by selectively introducing redundancy into the information, typically using an error correction code (ECC), such as a polar code or a low-density parity-check (LDPC) code). The network node 110 or the UE 120 (for example, using the processing system 145 or one or more modems) may further perform spatial processing (for example, precoding) on the encoded information to generate one or more processed or precoded signals for downlink or uplink transmission, respectively. In some examples, the network node 110a or the UE 120a may perform codebook-based precoding or non-codebook-based precoding. Codebook-based precoding may involve selecting a precoder (for example, a precoding matrix) using a codebook. For example, the network node 110a may provide precoding information indicating which precoder, defined by the codebook, is to be used by the UE 120a. Non-codebook-based precoding may involve selecting or deriving a precoder based on, or otherwise associated with, one or more downlink or uplink signal measurements. The network node 110a or the UE 120a may transmit the processed downlink or uplink signals, respectively, via one or more antennas.

The network node 110a or the UE 120a may receive uplink signals or downlink signals, respectively, via one or more antennas. The network node 110a or the UE 120a (for example, using the processing system 145 or the processing system 140, respectively, or one or more coupled modems) may perform signal processing (for example, in accordance with the MCS) on the received uplink or downlink signals, respectively (such as filtering, amplification, demodulation, analog-to-digital conversion, an FFT operation, demultiplexing, deinterleaving, de-mapping, equalization, interference cancellation, or decoding, among other examples), to map the received signal(s) to a sequence of binary bits (for example, received information) that estimates the information transmitted by the network node 110 or the UE 120 via the downlink or uplink signals. The network node 110a or the UE 120a (for example, using the processing system 145 or the processing system 140, respectively, or a coupled decoder or one or more modems) may decode the received information (such as by using an ECC, a decoding operation, or an FEC operation) to detect errors or correct bit errors in the received information to generate decoded information. The decoded information may estimate the information transmitted via the downlink or uplink signals.

In some examples, a UE 120 and a network node 110 may perform MIMO communication. MIMO communication generally refers to transmitting or receiving multiple signals (such as multiple layers or multiple data streams) simultaneously over the same time and frequency resources. A network node 110 or a UE 120 may communicate using single-user MIMO or multi-user MIMO (MU-MIMO), the latter of which being used by a network node 110 to simultaneously transmit signals to multiple UEs 120. MIMO techniques may involve spatial multiplexing (multi-layer transmission) or beamforming. To implement beamforming, the amplitudes or phases of signals transmitted via antenna elements may be modulated and shifted relative to each other (such as by manipulating a phase shift, a phase offset, or an amplitude) to generate one or more beams. For example, a network node 110 may generate one or more beams 160a, and a UE 120 may generate one or more beams 160b. The term “beam” may refer to a directional transmission of a wireless signal toward a receiving device or otherwise in a desired direction, a directional reception of a wireless signal from a transmitting device or otherwise in a desired direction, a direction associated with such a directional transmission or directional reception, a set of directional resources associated with a signal transmission or signal reception (for example, an angle of arrival, a horizontal direction, or a vertical direction), or a set of parameters or resources associated with one or more aspects of a directional signal, among other examples.

In some examples, a network node 110 or a UE 120 may implement massive MIMO, which may be associated with an increased (for example, “massive”) quantity of antennas at the network node 110 or at the UE 120, such as in a network implementing mmWave technology, which enables more precise beamforming or reduced interference. In some examples, the wireless communication network 100 may implement multi-TRP (mTRP) operation (including redundant transmission or reception on multiple TRPs) or non-coherent joint transmission (NC-JT).

The network node 110 and the UE 120 may establish a communication link or beam pair, and otherwise increase reliability, throughput, signal strength, or other signal properties for MIMO communications, by performing beam management operations, such as an initial beam acquisition operation, a beam refinement operation, or a beam recovery operation. For example, an initial beam acquisition operation may involve the network node 110 transmitting signals (for example, SSBs or other signals) via respective beams (for example, of the beams 160 of the network node 110) and the UE 120 receiving and measuring the signal(s) via respective beams of multiple beams (for example, from the beams 160 of the UE 120) to identify a best beam (or beam pair) for communication between the UE 120 and the network node 110. A beam refinement operation may involve a first device (for example, the UE 120 or the network node 110) transmitting signal(s) via a subset of beams (for example, identified based on, or otherwise associated with, measurements reported as part of one or more other beam management operations). A second device (for example, the network node 110 or the UE 120) may receive the signal(s) via a single beam (for example, to identify the best beam for communication from the subset of beams). The beam(s) may be identified or defined via one or more spatial parameters, such as a transmission configuration indicator (TCI) state or a quasi co-location (QCL) parameter, among other examples.

Some aspects and techniques as described herein may be implemented, at least in part, using an artificial intelligence (AI) program (for example, referred to herein as an “AI/ML model”), such as a program that includes a machine learning (ML) model or an artificial neural network (ANN) model. The AI/ML model may be deployed at one or more devices 165 (for example, one or more network nodes 110, one or more UEs 120, one or more servers, or one or more components of a cloud computing network, among other examples). For example, in a deployment in which AI/ML functionality is performed independently at a device 165, sometimes referred to as “overlay AI/ML,” the AI/ML model (or an instance or portion of the AI/ML model) may be deployed at a UE 120 (for example, by the processing system 140), a network node 110 (for example, by the processing system 145), one or more servers, or one or more components of a cloud computing network, among other examples. Additionally, or alternatively, in a deployment where AI/ML functionality is coordinated between different devices 165, sometimes referred to as “coordinated AI/ML,” or performed at all device and network layers, sometimes referred to as “native AI/ML,” the AI/ML model (or an instance of the AI/ML model) may be deployed at multiple devices 165 (for example, a first portion of the AI/ML model may be deployed at a UE 120 and a second portion of the AI/ML model may be deployed at a network node 110). In other examples of coordinated AI/ML or native AI/ML, a first AI/ML model may be deployed at a UE 120 and a second AI/ML model may be deployed at a network node 110. The AI/ML model(s) may be configured to enhance various aspects of the wireless communication network 100 (for example, to increase privacy, reliability, or efficient use of network bandwidth, or to reduce latency, among other examples). For example, the AI/ML model(s) may be trained to identify patterns or relationships in data corresponding to the wireless communication network 100, a device, or an air interface, among other examples. The AI/ML model(s) may support operational decisions relating to one or more aspects associated with wireless communications devices, networks, or services.

Accordingly, in some examples, the AI/ML model(s) may enable A l-as-a-Service (for example, an end-to-end AI/ML service via a user plane) for use cases, such as a self-organizing network (SON), minimization of drive test (MDT), quality of experience (QoE), positioning, sensing, predictive mobility, or traffic prediction, among other examples. In some examples, AI-as-a-Service use cases may include measurement collection reporting by a UE 120, device selection criteria (for example, according to a geographical area where measurements are to be collected or UE capabilities to be used to collected measurements), or reporting configurations (for example, reporting parameters such as location, time, or sensor information, among other examples). Additionally, or alternatively, the AI/ML model(s) may enable AI/ML procedures (for example, RAN-triggered service establishment, configuration, inferencing using UE-side or network-side models, performance monitoring or management, or capability signaling, among other examples). Additionally, or alternatively, the AI/ML model(s) may enable RAN-based AI/ML services via one or more application program interfaces (APIs) or management interfaces for use cases, such as beam management, radio resource monitoring (RRM) relaxation, mobility prediction, load prediction, network energy savings, or coverage and capacity improvements, among other examples).

In some aspects, the UE 120 may include a communication manager 150. As described in more detail elsewhere herein, the communication manager 150 may receive, from a network node, a first message in accordance with a polar coding scheme; transmit, to the network node, an indication of one or more frozen bits associated with the polar coding scheme, wherein the one or more frozen bits are selected in accordance with the first message; and receive, from the network node, a second message in accordance with the one or more frozen bits. Additionally, or alternatively, the communication manager 150 may perform one or more other operations described herein.

In some aspects, the network node 110 may include a communication manager 155. As described in more detail elsewhere herein, the communication manager 155 may transmit, to a UE, a first message in accordance with a polar coding scheme; receive, from the UE, an indication of one or more frozen bits associated with the polar coding scheme, wherein the one or more frozen bits are selected in accordance with the first message; and transmit, to the UE, a second message in accordance with the one or more frozen bits. Additionally, or alternatively, the communication manager 155 may perform one or more other operations described herein.

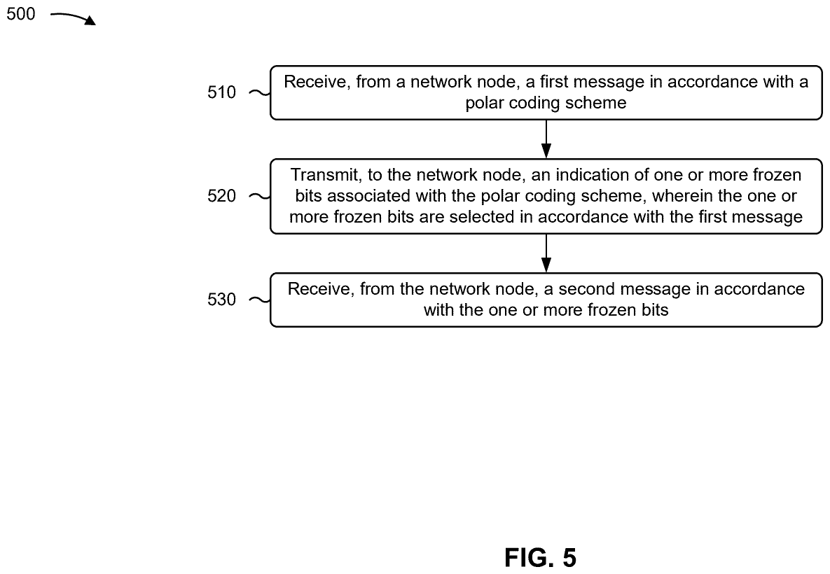

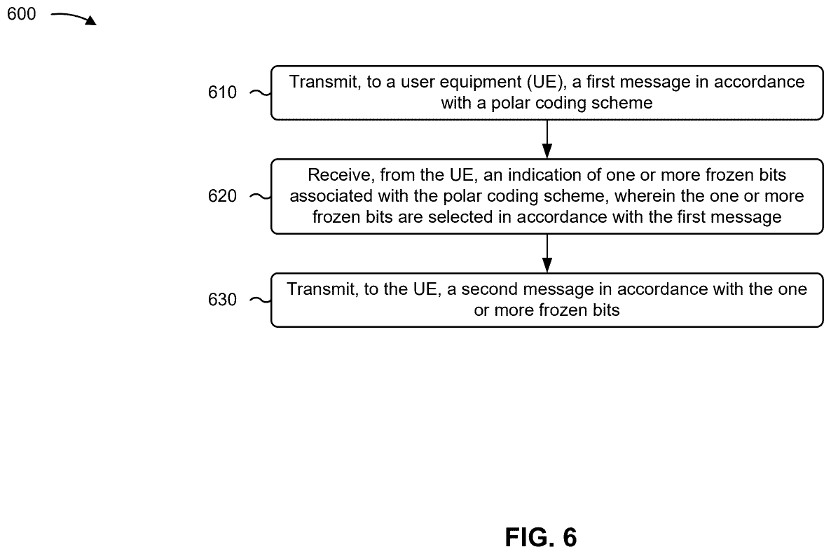

The network node 110, the processing system 145 of the network node 110, the UE 120, the processing system 140 of the UE 120, or any other component(s) of FIG. 1 may implement one or more techniques or perform one or more operations associated with frozen bit selection for polar coding schemes, as described in more detail elsewhere herein. For example, the processing system 145 of the network node 110, or the processing system 140 of the UE 120 may perform or direct operations of, for example, process 500 of FIG. 5, process 600 of FIG. 6, or other processes as described herein (alone or in conjunction with one or more other processors). Memory of the network node 110 may store data and program code (or instructions) for the network node 110. In some examples, the memory of the network node 110 may store data relating to a UE 120, such as RRC state information or a UE context. Memory of a UE 120 may store data and program code (or instructions) for the UE 120, such as context information. In some examples, the memory of the UE 120 or the memory of the network node 110 may include a non-transitory computer-readable medium storing a set of instructions for wireless communication. For example, the set of instructions, when executed by one or more processors (for example, of the processing system 145 or the processing system 140) of the network node 110, or the UE 120, may cause the one or more processors to perform process 500 of FIG. 5, process 600 of FIG. 6, or other processes as described herein. In some examples, executing instructions may include running the instructions, converting the instructions, compiling the instructions, or interpreting the instructions, among other examples.

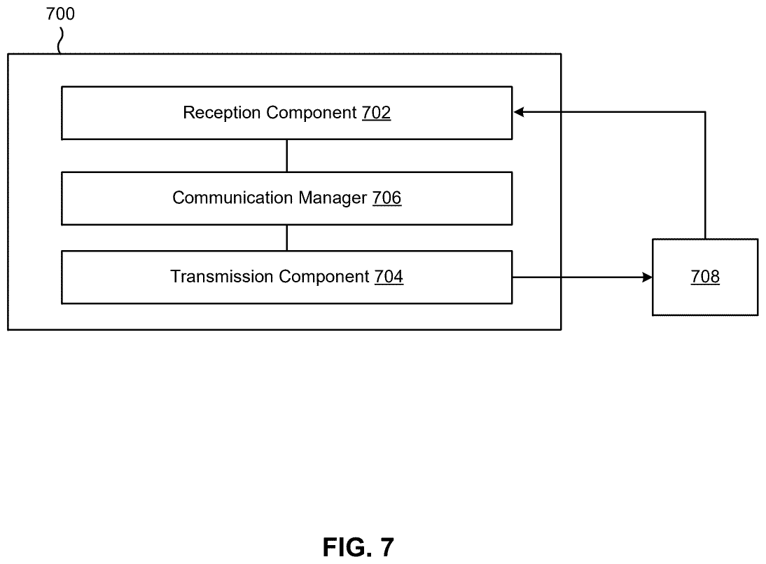

In some aspects, a UE (e.g., the UE 120) includes means for receiving, from a network node, a first message in accordance with a polar coding scheme; means for transmitting, to the network node, an indication of one or more frozen bits associated with the polar coding scheme, wherein the one or more frozen bits are selected in accordance with the first message; or means for receiving, from the network node, a second message in accordance with the one or more frozen bits. The means for the UE to perform operations described herein may include, for example, one or more of communication manager 150, processing system 140, a radio, one or more RF chains, one or more transceivers, one or more antennas, one or more modems, a reception component (for example, reception component 702 depicted and described in connection with FIG. 7), or a transmission component (for example, transmission component 704 depicted and described in connection with FIG. 7), among other examples.

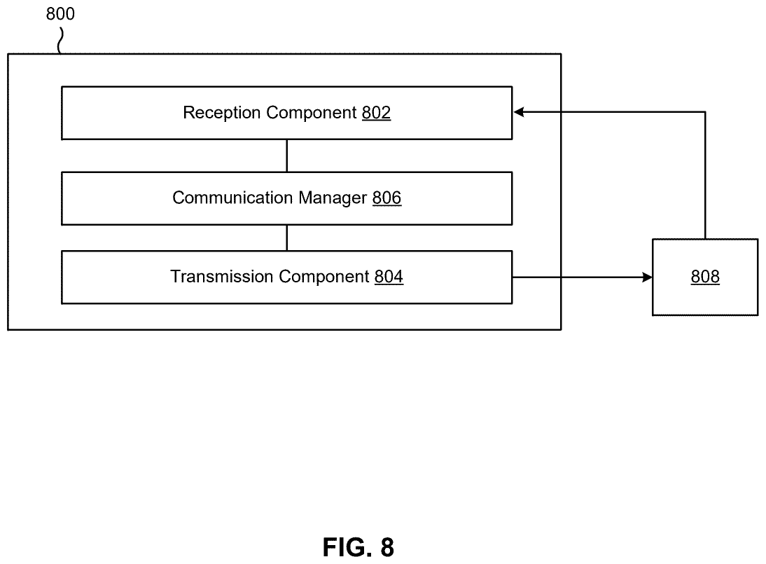

In some aspects, a network node (e.g., the network node 110) includes means for transmitting, to a UE, a first message in accordance with a polar coding scheme; means for receiving, from the UE, an indication of one or more frozen bits associated with the polar coding scheme, wherein the one or more frozen bits are selected in accordance with the first message; or means for transmitting, to the UE, a second message in accordance with the one or more frozen bits. The means for the network node to perform operations described herein may include, for example, one or more of communication manager 155, processing system 145, a radio, one or more RF chains, one or more transceivers, one or more antennas, one or more modems, a reception component (for example, reception component 802 depicted and described in connection with FIG. 8), or a transmission component (for example, transmission component 804 depicted and described in connection with FIG. 8), among other examples.

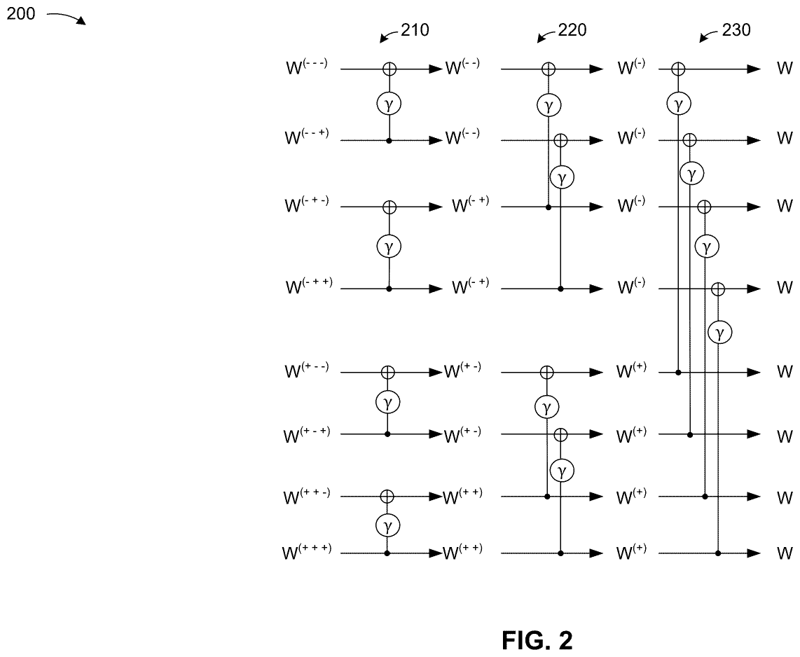

FIG. 2 is a diagram illustrating an example of a polar encoding operation 200 in accordance with the present disclosure. M ore particularly, as described herein, wireless communications, such as control channel communications, may be encoded using polar coding to improve resilience to non-ideal channel conditions. Polar encoding may generally involve recursively constructing a codeword c having a length N. In some examples, encoding with an (N=2^{m}, K) code defined over a Galois Field (GF) with four elements (GF(4)), the codeword

$$c = u {( \begin{matrix}1 & 0 \\ γ & 1\end{matrix} )}^{⊗ m} ,$$

where uᵢ, cᵢ∈GF(4), γ is an element of GF(4) not equal to 0 or 1, and i is an integer, i∈[0, N−1]. A symbol uᵢ of an encoded communication may carry information (for example, a two-bit payload in GF(4) or a one-bit payload in GF(2)) or may be frozen (for example, having a fixed value, such as uᵢ=0). N may be referred to herein as a value defining a plurality of symbols of the encoded communication. In the binary case (GF(2)), γ=1.

The matrix

$${( \begin{matrix}1 & 0 \\ γ & 1\end{matrix} )}^{⊗ m}$$

may polarize 2^{m} copies of a channel W into subchannels W⁽ⁱ⁾, which may be almost noisy (for example, I(W⁽ⁱ⁾)→0) or almost noiseless (for example, I(W⁽ⁱ⁾)→2). As an example, subchannels W⁽ⁱ⁾ may be polarized into highly reliable (for example, low noise) subchannels W⁽ⁱ⁾ and highly unreliable (for example, noisy) subchannels W⁽ⁱ⁾. For example, for GF(4), the capacities of the subchannels W⁽ⁱ⁾, I(W⁽ⁱ⁾), may approach two for highly reliable subchannels W⁽ⁱ⁾ and 0 for highly unreliable subchannels W⁽ⁱ⁾. If GF(2), γ=1, and subchannels W⁽ⁱ⁾ may be present where the capacities I(W⁽ⁱ⁾) approach one (for example, I(W⁽ⁱ⁾)→1).

Polar coding provides for a set of information symbols or information bits i₀, . . . i_{K-1} to be mapped to reliable symbol positions (referred to as information bit locations) and for unreliable symbols (in frozen locations) to be replaced with frozen symbols. For example, the information symbols i₀, . . . i_{K-1} may correspond to the K largest capacities I(W⁽ⁱ⁾). For example, a transmitter may transmit the information symbols i₀, . . . i_{K-1} through the subchannels W⁽ⁱ⁾ that have the K largest capacities I(W⁽ⁱ⁾).

The polar encoding operation 200 may include coupling a plurality of subchannels W⁽ⁱ⁾ over multiple phases 210-230. Phase 210 involves coupling neighboring subchannels W⁽ⁱ⁾. Phase 220 involves coupling subchannels W⁽ⁱ⁾ separated by one subchannel W⁽ⁱ⁾. Phase 230 involves coupling subchannels W⁽ⁱ⁾ separated by three subchannels W⁽ⁱ⁾. Polar decoding may involve performing the polar encoding operation 200 in reverse (for example, starting with phase 230, which is followed by phase 220, which is followed by phase 210).

Polar coding is described herein with reference to a general polarization kernel

$$G = ( \begin{matrix}1 & 0 \\ γ & 1\end{matrix} ) ,$$

where for GF(4), γ∈{1, α, α²}, and α is the primitive element of GF(22). Thus, the elements of GF(22) may include {0, 1, α, α²=α+1}, which may be considered as the elements {00, 01, 10, 11} of a two-dimensional vector space over GF(2). The summation of the elements may be defined coordinate-wise (for example, where each coordinate is a single bit), and for multiplication of the elements, the following properties may be used: 0·x=0, 1·x=x, and α³=1. As described herein, for encoding in nonbinary polar coding, a recursive structure

$${( \begin{matrix}1 & 0 \\ γ & 1\end{matrix} )}^{⊗ m}$$

may be used. For GF(2), the polarization kernel

$$G = ( \begin{matrix}1 & 0 \\ 1 & 1\end{matrix} )$$

and for encoding in binary polar coding, a recursive structure

$${( \begin{matrix}1 & 0 \\ 1 & 1\end{matrix} )}^{⊗ m}$$

may be used. Furthermore, an N×N polarization kernel may be denoted

$$G = {[ \begin{matrix}1 & 1 \\ 1 & 0\end{matrix} ]}^{⊗ m} ,$$

where m=log ₂ N.

In some aspects, a UE 120 may be configured to estimate frozen bits and indicate the frozen bits to a network node 110 for use in communications with the UE 120. In some examples, the UE 120 may receive a downlink message from a network node 110 encoded using a default set of frozen bits. In some aspects, the UE 120 may be configured to estimate one or more BERs from a decoder output in accordance with the reception of the message. For example, the UE 120 may estimate a BER using an LLR decoder output for all bits of code blocks that have passed a CRC, including frozen bits and information bits, and the UE 120 may be configured to discard code blocks that did not pass the CRC. In some aspects, the UE 120 may be configured to transmit, to the network node 110, an indication of the selected frozen bits. For example, the UE 120 may transmit a report that includes a table of bit indexes that indicates which bits are frozen bits or information bits, or the UE 120 may transmit a request to freeze or unfreeze specific bits (e.g., relative to the set of default bits). Additionally, or alternatively, the UE 120 may transmit an indication of one or more estimated BERs for one or more bits (e.g., for one or more subchannels corresponding to selected frozen bits, information bits, or a combination thereof). In some aspects, the network node 110 may transmit subsequent messages to the UE 120 in accordance with the updated frozen bits based on the indication of the frozen bits transmitted by the UE 120. Additionally, or alternatively, the network node 110 may select frozen bits for uplink messages transmitted by the UE 120 based on the indication of the frozen bits or the indication of the one or more estimated BERs. In some aspects, the network node 110 may transmit, to the UE 120, an indication of the updated frozen bits for uplink or downlink communications.

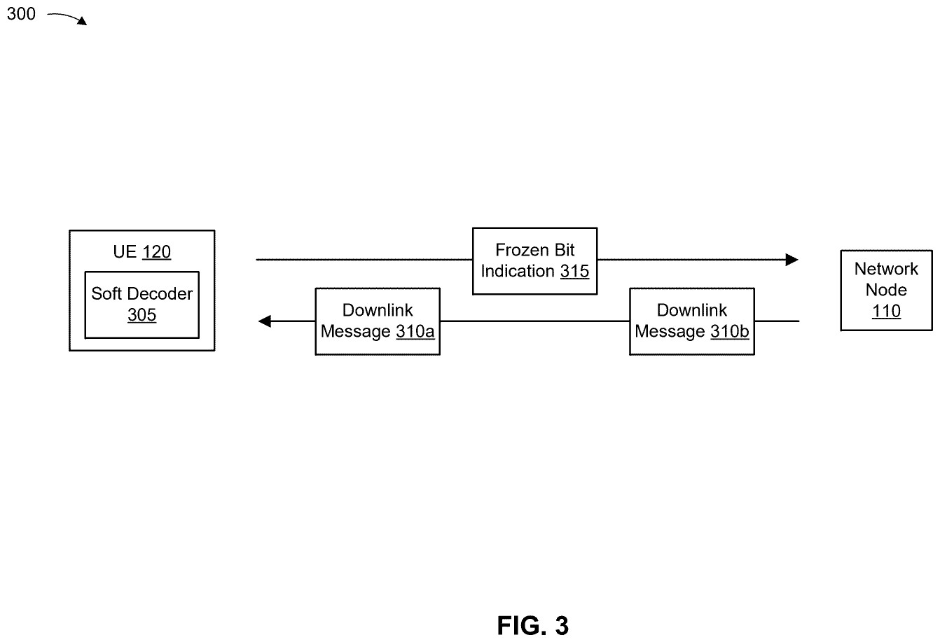

FIG. 3 is a diagram illustrating an example 300 associated with frozen bit selection for polar coding schemes. As shown in FIG. 3, example 300 includes communication between a network node 110 and a UE 120. In some aspects, the network node 110 and the UE 120 may be included in a wireless network, such as wireless network 100. The network node 110 and the UE 120 may communicate via a wireless access link, which may include an uplink and a downlink.

In some aspects, the UE 120 may be equipped with a soft decoder 305 (e.g., a successive cancellation (SC) decoder), which may be used for decoding received messages. In some examples, the soft decoder 305 may be used to calculate or process LLRs, and each LLR may be a measure that quantifies a reliability of a respective received bit (e.g., a likelihood that the respective received bit is a ‘1’ or a ‘0’). In some examples, the UE 120 may receive a downlink message 310a (e.g., a downlink data message, such as a PDSCH message) from the network node 110. The UE 120 may be configured to calculate one or more LLRs for received bits of the downlink message 310a.

In some aspects, the UE 120 may be configured to estimate frozen bits in accordance with reception of the downlink message 310a. For example, the downlink message 310a may be transmitted by the network node 110 in accordance with a default set of frozen bits. In some examples, in polar coding, a communication channel may be polarized into reliable subchannels corresponding to bits having a BER that approaches 0 (e.g., having a symmetric capacity that approaches 1) and unreliable subchannels corresponding to bits having a BER that approaches 0.5 (e.g., having a symmetric capacity that approaches 0). The UE 120 may estimate a BER for one or more bits of the downlink message 310a, where each bit may correspond to a subchannel of the downlink message 310a.

In some aspects, the UE 120 may be configured to select frozen bits for communications in accordance with the estimated BER or estimated bit capacities (e.g., symmetric capacities). For example, the UE 120 may be configured to select frozen bits such that the frozen bits are assigned to the unreliable subchannels, which may correspond to bits having a BER of 0.5 or approaching a BER of 0.5 (e.g., satisfying a first BER threshold) or bits having a bit capacity that is or approaches 1 (e.g., satisfying a first bit capacity threshold). Additionally, or alternatively, the UE 120 may be configured to select information bits such that the information bits are assigned to the reliable subchannels, which may correspond to bits having a BER of 0 or approaching a BER of 0 (e.g., satisfying a second BER threshold) or bits having a bit capacity that is or approaches 0 (e.g., satisfying a second bit capacity threshold).

In some aspects, the UE 120 may use the soft decoder 305 to estimate the bit BERs and select the frozen bits for polar coding. For example, the UE 120 may be configured to estimate a BER for a bit based on an output of the soft decoder 305. In some examples, the BERs may be estimated based on LLR values at the output of the soft decoder 305 before hard slicing (e.g., associated with bit value selection or decision making based on the LLR values). For example, the LLR values may be obtained prior to a slicing operation (e.g., hard slicing) of one or more bits locations for one or more frozen bits, one or more information bits, or a combination thereof. In some examples, the UE 120 may estimate a BER value for a bit i, BERᵢ, in accordance with Equation 1 below:

$${BER}_{i} = 1 - \frac{1}{1 + {e}^{- \vert {LLR}_{i , {decoder}_{out}} \vert}} \qquad ( 1 )$$

where |LLR_{i,decoder}_{ₒᵤₜ}| may be the absolute value of the LLR for the bit i at the output of the soft decoder 305 before slicing (e.g., hard slicing).

In some cases, if the LLR is biased (e.g., due to error propagation), the BER estimate may be invalid, which may affect the selection of the frozen bits. Accordingly, the UE 120 may be configured to estimate BERs for bits that are not associated with error propagation. In some aspects, the UE 120 may be configured to estimate BERs for bits of code blocks (e.g., polar code blocks) within the downlink message 310a that are not associated with errors. For example, the UE 120 may estimate BERs for bits of code blocks for which a CRC was successful (e.g., CRC passed). In some examples, the UE 120 may be configured to discard code blocks for which a CRC was unsuccessful (e.g., CRC failed).

Accordingly, the UE 120 may estimate BERs without knowledge of the true data transmitted by the network node 110, as in a Monte Carlo simulation, which may allow the UE 120 to estimate BERs in an online setting. Additionally, the convergence of the estimation of the BERs may be significantly faster than hard decision estimation associated with other frozen bit selection techniques. Furthermore, the BER estimation allows frozen bits to adapt to changing channel conditions between the network node 110 and the UE 120.

In some aspects, the UE 120 may transmit a frozen bit indication 315 to the network node 110, and the bit indication 315 may indicate the selected frozen bits to the network node 110. For example, the frozen bit indication 315 may be a report of frozen bits and information bits. The report may include a sorted table of bit indexes, which may indicate which bits are selected as frozen bits and which bits are selected as information bits. For example, the table may be sorted in accordance with a reliability (e.g., a BER or symmetric capacity) of each bit (e.g., in ascending or descending order), which may indicate which bits are to be selected as frozen bits and information bits.

Additionally, or alternatively, the frozen bit indication 315 may include one or more requests to freeze or unfreeze one or more specific bits. For example, the UE 120 may transmit a request to freeze one or more bits, unfreeze one or more bits, or a combination thereof. In some aspects, the request may include a first parameter k1, which may indicate a set of one or more bits to unfreeze and a second parameter k2, which may indicate a set of one or more bits to freeze. In some examples, the first parameter k1 and the second parameter k2 may be parameters configured for reporting by the network node 110. For example, when the first parameter k1 is set to 1, the UE 120 may request to unfreeze a single bit i, and when the second parameter k2 is set to 1, the UE 120 may request to freeze a single bit j. In some aspects, the UE 120 may request a rate change (e.g., a change to the ratio between frozen bits and information bits) when the first parameter k1 does not equal the second parameter k2.

Additionally, or alternatively, the UE 120 may report the estimated BERs for some or all of the bits. For example, the frozen bit indication 315 may include the estimated BER for at least one bit, such as bits requested to be frozen, bits requested to be unfrozen, all bits, or a combination thereof.

In some aspects, the network node 110 may receive the frozen bit indication 315 and may update the frozen bits in accordance with the frozen bit indication 315. In some examples, the network node 110 may evaluate the frozen bit indication 315, and the network node 110 may accept or decline the updates requested by the UE 120. In some cases, the network node 110 may transmit a configuration or a message that indicates whether the frozen bit indication 315 is accepted. Additionally, or alternatively, the network node 110 may indicate an updated frozen bit configuration that may fully or only partially accept the updates indicated by the frozen bit indication 315.

The network node 110 may use the updated frozen bits in polar encoding for subsequent transmissions to the UE 120. For example, the network node 110 may transmit a downlink message 310b to the UE 120, and the downlink message 310b may be encoded based on the newly selected frozen bits or information bits. Accordingly, the dynamic adjustment of frozen bits may improve the reliability and performance of the communication link, especially in varying channel conditions. The UE 120 may receive the downlink message 310b and may decode the downlink message 310b using the updated frozen bits or information bits, thereby enhancing the overall communication efficiency and robustness.

In some aspects, a similar approach for selecting and indicating frozen bits can may be used for polar coding for uplink transmissions (e.g., for PUSCH messages, PDSCH messages, or both). For example, the network node 110 may estimate BERs as described herein (e.g., based on an uplink message transmitted by the UE 120), and the network node 110 may indicate frozen bits to the UE 120 based on the estimated BERs.

Additionally, or alternatively, the network node 110 may estimate frozen bits based on reciprocity estimations. For example, the network node 110 may estimate reception parameters (e.g., BERs) based on the transmitted downlink message 310a, and the network node 110 may use the estimated reception parameters to update the frozen bits or information bits. In some aspects, when the network node 110 updates frozen bits or information bits based on estimations performed by the network node 110 (e.g., from uplink message reception or based on reciprocity for transmitted downlink messages), the network node 110 may indicate the updates to the UE 120 via one or more messages or updated configurations. In some cases, indicating the updates to the UE 120 may be based on a capability of the UE 120 to support an updated frozen bit set, which may be indicated by the UE 120 (e.g., via a UE capability message).

As indicated above, FIG. 3 is provided as an example. Other examples may differ from what is described with respect to FIG. 3.

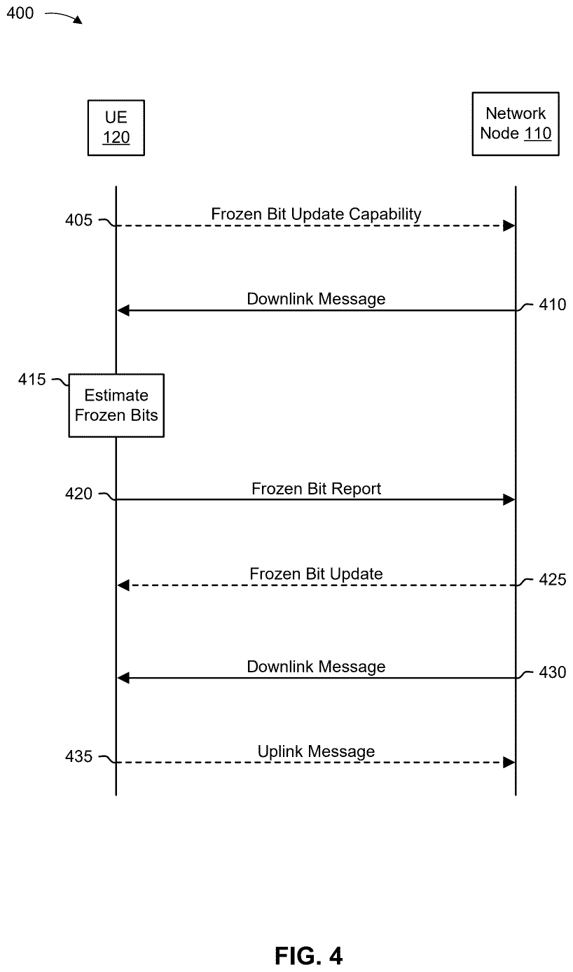

FIG. 4 is a diagram illustrating an example 400 associated with frozen bit selection for polar coding schemes. As shown in FIG. 4, example 400 includes communication between a network node 110 and a UE 120. In some aspects, the network node 110 and the UE 120 may be included in a wireless network, such as wireless network 100. The network node 110 and the UE 120 may communicate via a wireless access link, which may include an uplink and a downlink.

As shown by reference number 405, the UE 120 may transmit an indication of a capability of the UE 120 associated with frozen bit updates. For example, the capability may indicate that the UE 120 supports estimation to update a set of frozen bits (e.g., based on BER estimation, as described with respect to FIG. 3) and communication in accordance with the updated set of frozen bits. In some examples, the capability may be indicated via a UE capability message.

As shown by reference number 410, the network node 110 may transmit a downlink message to the UE 120. In some examples, the downlink message may be encoded using a default set of frozen bits, as described with respect to FIG. 3. As shown by reference number 415, the UE 120 may estimate a set of frozen bits in accordance with receiving the downlink message. For example, the UE 120 may be configured to estimate BERs for the received bits of code blocks of the downlink message that pass a CRC, as described with respect to FIG. 3.

As shown by reference number 420, the UE 120 may transmit a frozen bit report that may indicate frozen bits suggested for freezing or unfreezing by the UE 120. In some aspects, the frozen bit report may include a sorted table of bit indexes indicating frozen bits and information bits, one or more requests to freeze or unfreeze specific bits, estimated BERs for one or more bits, or a combination thereof, as described with respect to FIG. 3.

As shown by reference number 425, upon receiving the frozen bit report, the network node 110 may evaluate the suggested updates indicated by the frozen bit report, and the network node 110 may transmit an update message indicating updated frozen bits. For example, the network node 110 may transmit the update message to the UE 120 indicating a new configuration of frozen bits, which may be based on the frozen bit report. The update message may ensure that the frozen bits are synchronized between the network node 110 and the UE 120 for subsequent communications, as described with respect to FIG. 3. In some aspects, the update message may indicate frozen bits to be used for uplink messages (e.g., PUSCH messages), downlink messages (e.g., PDSCH messages), or a combination thereof. For example, the network node 110 may determine a frozen bit set of downlink communications based on reciprocity in accordance with the frozen bit report or the downlink message.

As shown by reference number 430, following the frozen bit update, the network node 110 may transmit a second downlink message to the UE 120, as described with respect to FIG. 3. The second downlink message is encoded based on the newly selected frozen bits, improving the reliability and performance of the communication link. Additionally, or alternatively, as shown by reference number 435, the UE 120 may transmit an uplink message to the network node 110 using the updated frozen bits configuration. The dynamic adjustment of frozen bits enhances the overall communication efficiency and robustness, while accommodating varying channel conditions.

As indicated above, FIG. 4 is provided as an example. Other examples may differ from what is described with respect to FIG. 4.

FIG. 5 is a diagram illustrating an example process 500 performed, for example, at a UE or an apparatus of a UE. Example process 500 is an example where the apparatus or the UE (e.g., UE 120) performs operations associated with frozen bit selection and indication for polar coding schemes.

As shown in FIG. 5, in some aspects, process 500 may include receiving, from a network node, a first message in accordance with a polar coding scheme (block 510). For example, the UE (e.g., using reception component 702 or communication manager 706, depicted in FIG. 7) may receive, from a network node, a first message in accordance with a polar coding scheme, as described above.

As further shown in FIG. 5, in some aspects, process 500 may include transmitting, to the network node, an indication of one or more frozen bits associated with the polar coding scheme, wherein the one or more frozen bits are selected in accordance with the first message (block 520). For example, the UE (e.g., using transmission component 704 or communication manager 706, depicted in FIG. 7) may transmit, to the network node, an indication of one or more frozen bits associated with the polar coding scheme, wherein the one or more frozen bits are selected in accordance with the first message, as described above.

As further shown in FIG. 5, in some aspects, process 500 may include receiving, from the network node, a second message in accordance with the one or more frozen bits (block 530). For example, the UE (e.g., using reception component 702 or communication manager 706, depicted in FIG. 7) may receive, from the network node, a second message in accordance with the one or more frozen bits, as described above.

Process 500 may include additional aspects, such as any single aspect or any combination of aspects described below or in connection with one or more other processes described elsewhere herein.

In a first aspect, process 500 includes transmitting, to the network node, an indication of a capability associated with support for estimation of frozen bits and communications using estimated frozen bits.

In a second aspect, alone or in combination with the first aspect, process 500 includes transmitting, to the network node, an indication of a plurality of bit indexes corresponding to a plurality of bits, wherein the plurality of bits includes the one or more frozen bits and one or more non-frozen bits.

In a third aspect, alone or in combination with one or more of the first and second aspects, process 500 includes transmitting, to the network node, an indication of a first set of one or more bits to freeze, a second set of one or more bits to unfreeze, or a combination thereof, for the polar coding scheme.

In a fourth aspect, alone or in combination with one or more of the first through third aspects, a rate change is requested for the polar coding scheme in accordance with a first quantity of the first set of one or more bits being different from a second quantity of the second set of one or more bits.

In a fifth aspect, alone or in combination with one or more of the first through fourth aspects, the one or more frozen bits are selected in accordance with one or more bit error rates, one or more bit capacities, or both, corresponding to a set of code blocks associated with the first message.

In a sixth aspect, alone or in combination with one or more of the first through fifth aspects, process 500 includes transmitting, to the network node, an indication of the one or more bit error rates, the one or more bit capacities, or both.

In a seventh aspect, alone or in combination with one or more of the first through sixth aspects, the one or more bit error rates, the one or more bit capacities, or both, are estimated in accordance with respective LLRs obtained in accordance with a soft decoder output prior to a slicing of one or more bit locations of the soft decoder output, the one or more bit locations corresponding to the one or more frozen bits, one or more information bits, and the respective LLRs are obtained for the set of one or more code blocks.

In an eighth aspect, alone or in combination with one or more of the first through seventh aspects, the one or more bit error rates are estimated in accordance with a subset of the set of one or more code blocks for which a cyclic redundancy check was successful.

In a ninth aspect, alone or in combination with one or more of the first through eighth aspects, process 500 includes receiving, from the network node, an indication of one or more updated frozen bits associated with downlink communications in accordance with the indication of the one or more frozen bits, and receiving, from the network node, a third message in accordance with the one or more updated frozen bits.

In a tenth aspect, alone or in combination with one or more of the first through ninth aspects, process 500 includes receiving, from the network node, an indication of one or more additional frozen bits associated with uplink transmissions, and transmitting, to the network node, a third message in accordance with the one or more additional frozen bits.

Although FIG. 5 shows example blocks of process 500, in some aspects, process 500 may include additional blocks, fewer blocks, different blocks, or differently arranged blocks than those depicted in FIG. 5. Additionally, or alternatively, two or more of the blocks of process 500 may be performed in parallel.

FIG. 6 is a diagram illustrating an example process 600 performed, for example, at a network node or an apparatus of a network node. Example process 600 is an example where the apparatus or the network node (e.g., network node 110) performs operations associated with frozen bit selection and indication for polar coding schemes.

As shown in FIG. 6, in some aspects, process 600 may include transmitting, to a UE, a first message in accordance with a polar coding scheme (block 610). For example, the network node (e.g., using transmission component 804 or communication manager 806, depicted in FIG. 8) may transmit, to a UE, a first message in accordance with a polar coding scheme, as described above.

As further shown in FIG. 6, in some aspects, process 600 may include receiving, from the UE, an indication of one or more frozen bits associated with the polar coding scheme, wherein the one or more frozen bits are selected in accordance with the first message (block 620). For example, the network node (e.g., using reception component 802 or communication manager 806, depicted in FIG. 8) may receive, from the UE, an indication of one or more frozen bits associated with the polar coding scheme, wherein the one or more frozen bits are selected in accordance with the first message, as described above.

As further shown in FIG. 6, in some aspects, process 600 may include transmitting, to the UE, a second message in accordance with the one or more frozen bits (block 630). For example, the network node (e.g., using transmission component 804 or communication manager 806, depicted in FIG. 8) may transmit, to the UE, a second message in accordance with the one or more frozen bits, as described above.

Process 600 may include additional aspects, such as any single aspect or any combination of aspects described below or in connection with one or more other processes described elsewhere herein.

In a first aspect, process 600 includes receiving, from the UE, an indication of a capability associated with support for estimation of frozen bits and communications using estimated frozen bits.

In a second aspect, alone or in combination with the first aspect, process 600 includes receiving, from the UE, an indication of a plurality of bit indexes corresponding to a plurality of bits, wherein the plurality of bits includes the one or more frozen bits and one or more non-frozen bits.

In a third aspect, alone or in combination with one or more of the first and second aspects, process 600 includes receiving, from the UE, an indication of a first set of one or more bits to freeze, a second set of one or more bits to unfreeze, or a combination thereof, for the polar coding scheme.

In a fourth aspect, alone or in combination with one or more of the first through third aspects, a rate change is requested for the polar coding scheme in accordance with a first quantity of the first set of one or more bits being different from a second quantity of the second set of one or more bits.

In a fifth aspect, alone or in combination with one or more of the first through fourth aspects, the one or more frozen bits are selected in accordance with one or more bit error rates, one or more bit capacities, or both, corresponding to a set of code blocks associated with the first message.

In a sixth aspect, alone or in combination with one or more of the first through fifth aspects, process 600 includes receiving, from the UE, an indication of the one or more bit error rates, the one or more bit capacities, or both.

In a seventh aspect, alone or in combination with one or more of the first through sixth aspects, the one or more bit error rates, the one or more bit capacities, or both, are estimated in accordance with respective LLRs obtained in accordance with a soft decoder output prior to a slicing of one or more bit locations of the soft decoder output, the one or more bit locations corresponding to the one or more frozen bits, one or more information bits, and the respective LLRs are obtained for the set of one or more code blocks.

In an eighth aspect, alone or in combination with one or more of the first through seventh aspects, the one or more bit error rates are estimated in accordance with a subset of the set of one or more code blocks for which a cyclic redundancy check was successful.

In a ninth aspect, alone or in combination with one or more of the first through eighth aspects, process 600 includes transmitting, to the UE, an indication of one or more updated frozen bits associated with downlink communications in accordance with the indication of the one or more frozen bits, and transmitting, to the UE, a third message in accordance with the one or more updated frozen bits.

In a tenth aspect, alone or in combination with one or more of the first through ninth aspects, process 600 includes transmitting, to the UE, an indication of one or more additional frozen bits associated with uplink transmissions, and receiving, from the UE, a third message in accordance with the one or more additional frozen bits.

Although FIG. 6 shows example blocks of process 600, in some aspects, process 600 may include additional blocks, fewer blocks, different blocks, or differently arranged blocks than those depicted in FIG. 6. Additionally, or alternatively, two or more of the blocks of process 600 may be performed in parallel.

FIG. 7 is a diagram of an example apparatus 700 for wireless communication. The apparatus 700 may be a UE (e.g., a UE 120), or a UE may include the apparatus 700. In some aspects, the apparatus 700 includes a reception component 702, a transmission component 704, or a communication manager 706, which may be in communication with one another (for example, via one or more buses or one or more other components). In some aspects, the communication manager 706 is the communication manager 150 described in connection with FIG. 1. As shown, the apparatus 700 may communicate with another apparatus 708, such as a UE or a network node (a network node 110, such as a CU, a DU, an RU, or a base station), using the reception component 702 and the transmission component 704. The communication manager 706 may be included in, or implemented via, a processing system (for example, the processing system 140 described in connection with FIG. 1) of the UE.

In some aspects, the apparatus 700 may be configured to perform one or more operations described herein in connection with FIG. 2-4. Additionally, or alternatively, the apparatus 700 may be configured to perform one or more processes described herein, such as process 500 of FIG. 5. In some aspects, the apparatus 700 or one or more components shown in FIG. 7 may include one or more components of the UE described in connection with FIG. 1. Additionally, or alternatively, one or more components shown in FIG. 7 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 702 may receive communications, such as reference signals, control information, data communications, or a combination thereof, from the apparatus 708. The reception component 702 may provide received communications to one or more other components of the apparatus 700. In some aspects, the reception component 702 may perform signal processing on the received communications, and may provide the processed signals to the one or more other components of the apparatus 700. In some aspects, the reception component 702 may include one or more components of the UE described above in connection with FIG. 1, such as a radio, one or more RF chains, one or more transceivers, or one or more modems, each of which may in turn be coupled with one or more antennas of the UE.

The transmission component 704 may transmit communications, such as reference signals, control information, data communications, or a combination thereof, to the apparatus 708. In some aspects, one or more other components of the apparatus 700 may generate communications and may provide the generated communications to the transmission component 704 for transmission to the apparatus 708. In some aspects, the transmission component 704 may perform signal processing on the generated communications, and may transmit the processed signals to the apparatus 708. In some aspects, the transmission component 704 may include one or more components of the UE described above in connection with FIG. 1, such as a radio, one or more RF chains, one or more transceivers, or one or more modems, each of which may in turn be coupled with one or more antennas of the UE described in connection with FIG. 1. In some aspects, the transmission component 704 may be co-located with the reception component 702.

The communication manager 706 may support operations of the reception component 702 or the transmission component 704. For example, the communication manager 706 may receive information associated with configuring reception of communications by the reception component 702 or transmission of communications by the transmission component 704. Additionally, or alternatively, the communication manager 706 may generate or provide control information to the reception component 702 or the transmission component 704 to control reception or transmission of communications.

The reception component 702 may receive, from a network node, a first message in accordance with a polar coding scheme. The transmission component 704 may transmit, to the network node, an indication of one or more frozen bits associated with the polar coding scheme, wherein the one or more frozen bits are selected in accordance with the first message. The reception component 702 may receive, from the network node, a second message in accordance with the one or more frozen bits.

The transmission component 704 may transmit, to the network node, an indication of a capability associated with support for estimation of frozen bits and communications using estimated frozen bits.

The transmission component 704 may transmit, to the network node, an indication of a plurality of bit indexes corresponding to a plurality of bits, wherein the plurality of bits includes the one or more frozen bits and one or more non-frozen bits.

The transmission component 704 may transmit, to the network node, an indication of a first set of one or more bits to freeze, a second set of one or more bits to unfreeze, or a combination thereof, for the polar coding scheme.

The transmission component 704 may transmit, to the network node, an indication of the one or more bit error rates, the one or more bit capacities, or both.

The reception component 702 may receive, from the network node, an indication of one or more updated frozen bits associated with downlink communications in accordance with the indication of the one or more frozen bits.

The reception component 702 may receive, from the network node, a third message in accordance with the one or more updated frozen bits.

The reception component 702 may receive, from the network node, an indication of one or more additional frozen bits associated with uplink transmissions.

The transmission component 704 may transmit, to the network node, a third message in accordance with the one or more additional frozen bits.

The number and arrangement of components shown in FIG. 7 are provided as an example. In practice, there may be additional components, fewer components, different components, or differently arranged components than those shown in FIG. 7. Furthermore, two or more components shown in FIG. 7 may be implemented within a single component, or a single component shown in FIG. 7 may be implemented as multiple, distributed components. Additionally, or alternatively, a set of (one or more) components shown in FIG. 7 may perform one or more functions described as being performed by another set of components shown in FIG. 7.

FIG. 8 is a diagram of an example apparatus 800 for wireless communication. The apparatus 800 may be a network node (e.g., a network node 110), or a network node may include the apparatus 800. In some aspects, the apparatus 800 includes a reception component 802, a transmission component 804, or a communication manager 806, which may be in communication with one another (for example, via one or more buses or one or more other components). In some aspects, the communication manager 806 is the communication manager 155 described in connection with FIG. 1. As shown, the apparatus 800 may communicate with another apparatus 808, such as a UE (e.g., a UE 120) or another network node (such as a CU, a DU, an RU, or a base station), using the reception component 802 and the transmission component 804. The communication manager 806 may be included in, or implemented via, a processing system (for example, the processing system 145 described in connection with FIG. 1) of the network node.

In some aspects, the apparatus 800 may be configured to perform one or more operations described herein in connection with FIG. 2-4. Additionally, or alternatively, the apparatus 800 may be configured to perform one or more processes described herein, such as process 600 of FIG. 6. In some aspects, the apparatus 800 or one or more components shown in FIG. 8 may include one or more components of the network node described in connection with FIG. 1. Additionally, or alternatively, one or more components shown in FIG. 8 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 802 may receive communications, such as reference signals, control information, data communications, or a combination thereof, from the apparatus 808. The reception component 802 may provide received communications to one or more other components of the apparatus 800. In some aspects, the reception component 802 may perform signal processing on the received communications, and may provide the processed signals to the one or more other components of the apparatus 800. In some aspects, the reception component 802 may include one or more components of the network node described above in connection with FIG. 1, such as a radio, one or more RF chains, one or more transceivers, or one or more modems, each of which may in turn be coupled with one or more antennas of the network node. In some aspects, the reception component 802 or the transmission component 804 may include or may be included in a network interface. The network interface may be configured to obtain or output signals for the apparatus 800 via one or more communications links, such as a backhaul link, a midhaul link, or a fronthaul link.

The transmission component 804 may transmit communications, such as reference signals, control information, data communications, or a combination thereof, to the apparatus 808. In some aspects, one or more other components of the apparatus 800 may generate communications and may provide the generated communications to the transmission component 804 for transmission to the apparatus 808. In some aspects, the transmission component 804 may perform signal processing on the generated communications, and may transmit the processed signals to the apparatus 808. In some aspects, the transmission component 804 may include one or more components of the network node described above in connection with FIG. 1, such as a radio, one or more RF chains, one or more transceivers, or one or more modems, each of which may in turn be coupled with one or more antennas of the network node described in connection with FIG. 1. In some aspects, the transmission component 804 may be co-located with the reception component 802.

The communication manager 806 may support operations of the reception component 802 or the transmission component 804. For example, the communication manager 806 may receive information associated with configuring reception of communications by the reception component 802 or transmission of communications by the transmission component 804. Additionally, or alternatively, the communication manager 806 may generate or provide control information to the reception component 802 or the transmission component 804 to control reception or transmission of communications.

The transmission component 804 may transmit, to a UE, a first message in accordance with a polar coding scheme. The reception component 802 may receive, from the UE, an indication of one or more frozen bits associated with the polar coding scheme, wherein the one or more frozen bits are selected in accordance with the first message. The transmission component 804 may transmit, to the UE, a second message in accordance with the one or more frozen bits.

The reception component 802 may receive, from the UE, an indication of a capability associated with support for estimation of frozen bits and communications using estimated frozen bits.

The reception component 802 may receive, from the UE, an indication of a plurality of bit indexes corresponding to a plurality of bits, wherein the plurality of bits includes the one or more frozen bits and one or more non-frozen bits.

The reception component 802 may receive, from the UE, an indication of a first set of one or more bits to freeze, a second set of one or more bits to unfreeze, or a combination thereof, for the polar coding scheme.

The reception component 802 may receive, from the UE, an indication of the one or more bit error rates, the one or more bit capacities, or both.

The transmission component 804 may transmit, to the UE, an indication of one or more updated frozen bits associated with downlink communications in accordance with the indication of the one or more frozen bits.

The transmission component 804 may transmit, to the UE, a third message in accordance with the one or more updated frozen bits.

The transmission component 804 may transmit, to the UE, an indication of one or more additional frozen bits associated with uplink transmissions.

The reception component 802 may receive, from the UE, a third message in accordance with the one or more additional frozen bits.

The number and arrangement of components shown in FIG. 8 are provided as an example. In practice, there may be additional components, fewer components, different components, or differently arranged components than those shown in FIG. 8. Furthermore, two or more components shown in FIG. 8 may be implemented within a single component, or a single component shown in FIG. 8 may be implemented as multiple, distributed components. Additionally, or alternatively, a set of (one or more) components shown in FIG. 8 may perform one or more functions described as being performed by another set of components shown in FIG. 8.

The following provides an overview of some Aspects of the present disclosure:

Aspect 1: A method of wireless communication performed by a UE, comprising: receiving, from a network node, a first message in accordance with a polar coding scheme; transmitting, to the network node, an indication of one or more frozen bits associated with the polar coding scheme, wherein the one or more frozen bits are selected in accordance with the first message; and receiving, from the network node, a second message in accordance with the one or more frozen bits.

Aspect 2: The method of Aspect 1, further comprising: transmitting, to the network node, an indication of a capability associated with support for estimation of frozen bits and communications using estimated frozen bits.

Aspect 3: The method of any of Aspects 1-2, further comprising: transmitting, to the network node, an indication of a plurality of bit indexes corresponding to a plurality of bits, wherein the plurality of bits includes the one or more frozen bits and one or more non-frozen bits.

Aspect 4: The method of any of Aspects 1-3, further comprising: transmitting, to the network node, an indication of a first set of one or more bits to freeze, a second set of one or more bits to unfreeze, or a combination thereof, for the polar coding scheme.

Aspect 5: The method of Aspect 4, wherein a rate change is requested for the polar coding scheme in accordance with a first quantity of the first set of one or more bits being different from a second quantity of the second set of one or more bits.

Aspect 6: The method of any of Aspects 1-5, wherein the one or more frozen bits are selected in accordance with one or more bit error rates, one or more bit capacities, or both, corresponding to a set of code blocks associated with the first message.

Aspect 7: The method of Aspect 6, further comprising: transmitting, to the network node, an indication of the one or more bit error rates, the one or more bit capacities, or both.

Aspect 8: The method of any of Aspects 6-7, wherein the one or more bit error rates, the one or more bit capacities, or both, are estimated in accordance with respective LLRs obtained in accordance with a soft decoder output prior to a slicing of one or more bit locations of the soft decoder output, the one or more bit locations corresponding to the one or more frozen bits, one or more information bits, and wherein the respective LLRs are obtained for the set of one or more code blocks.

Aspect 9: The method of any of Aspects 6-8, wherein the one or more bit error rates are estimated in accordance with a subset of the set of one or more code blocks for which a cyclic redundancy check was successful.

Aspect 10: The method of any of Aspects 1-9, further comprising: receiving, from the network node, an indication of one or more updated frozen bits associated with downlink communications in accordance with the indication of the one or more frozen bits; and receiving, from the network node, a third message in accordance with the one or more updated frozen bits.

Aspect 11: The method of any of Aspects 1-10, further comprising: receiving, from the network node, an indication of one or more additional frozen bits associated with uplink transmissions; and transmitting, to the network node, a third message in accordance with the one or more additional frozen bits.

Aspect 12: A method of wireless communication performed by a network node, comprising: transmitting, to a UE, a first message in accordance with a polar coding scheme; receiving, from the UE, an indication of one or more frozen bits associated with the polar coding scheme, wherein the one or more frozen bits are selected in accordance with the first message; and transmitting, to the UE, a second message in accordance with the one or more frozen bits.

Aspect 13: The method of Aspect 12, further comprising: receiving, from the UE, an indication of a capability associated with support for estimation of frozen bits and communications using estimated frozen bits.

Aspect 14: The method of any of Aspects 12-13, further comprising: receiving, from the UE, an indication of a plurality of bit indexes corresponding to a plurality of bits, wherein the plurality of bits includes the one or more frozen bits and one or more non-frozen bits.

Aspect 15: The method of any of Aspects 12-14, further comprising: receiving, from the UE, an indication of a first set of one or more bits to freeze, a second set of one or more bits to unfreeze, or a combination thereof, for the polar coding scheme.

Aspect 16: The method of Aspect 15, wherein a rate change is requested for the polar coding scheme in accordance with a first quantity of the first set of one or more bits being different from a second quantity of the second set of one or more bits.

Aspect 17: The method of any of Aspects 12-16, wherein the one or more frozen bits are selected in accordance with one or more bit error rates, one or more bit capacities, or both, corresponding to a set of code blocks associated with the first message.

Aspect 18: The method of Aspect 17, further comprising: receiving, from the UE, an indication of the one or more bit error rates, the one or more bit capacities, or both.

Aspect 19: The method of any of Aspects 17-18, wherein the one or more bit error rates, the one or more bit capacities, or both, are estimated in accordance with respective LLRs obtained in accordance with a soft decoder output prior to a slicing of one or more bit locations of the soft decoder output, the one or more bit locations corresponding to the one or more frozen bits, one or more information bits, and wherein the respective LLRs are obtained for the set of one or more code blocks.

Aspect 20: The method of any of Aspects 17-19, wherein the one or more bit error rates are estimated in accordance with a subset of the set of one or more code blocks for which a cyclic redundancy check was successful.

Aspect 21: The method of any of Aspects 12-20, further comprising: transmitting, to the UE, an indication of one or more updated frozen bits associated with downlink communications in accordance with the indication of the one or more frozen bits; and transmitting, to the UE, a third message in accordance with the one or more updated frozen bits.

Aspect 22: The method of any of Aspects 12-21, further comprising: transmitting, to the UE, an indication of one or more additional frozen bits associated with uplink transmissions; and receiving, from the UE, a third message in accordance with the one or more additional frozen bits.

Aspect 23: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-22.

Aspect 24: An apparatus for wireless communication at a device, the apparatus comprising one or more memories and one or more processors coupled to the one or more memories, the one or more processors configured to cause the device to perform the method of one or more of Aspects 1-22.

Aspect 25: An apparatus for wireless communication, the apparatus comprising at least one means for performing the method of one or more of Aspects 1-22.

Aspect 26: A non-transitory computer-readable medium storing code for wireless communication, the code comprising instructions executable by one or more processors to perform the method of one or more of Aspects 1-22.

Aspect 27: A non-transitory computer-readable medium storing a set of instructions for wireless communication, the set of instructions comprising one or more instructions that, when executed by one or more processors of a device, cause the device to perform the method of one or more of Aspects 1-22.

Aspect 28: A device for wireless communication, the device comprising a processing system that includes one or more processors and one or more memories coupled with the one or more processors, the processing system configured to cause the device to perform the method of one or more of Aspects 1-22.

Aspect 29: An apparatus for wireless communication at a device, the apparatus comprising one or more memories and one or more processors coupled to the one or more memories, the one or more processors individually or collectively configured to cause the device to perform the method of one or more of Aspects 1-22.

Aspect 30: A device comprising a processing system that includes one or more processors and one or more code-storing memories coupled with the one or more processors, the processing system configured to cause the device to perform the method of one or more of Aspects 1-22.

Aspect 31: A device comprising a processing system that includes processor circuitry and code-storing memory circuitry, the processing system configured to cause the device to perform the method of one or more of Aspects 1-22.

It will be apparent that systems or methods described herein may be implemented in different forms of hardware or a combination of hardware and software. A component being configured to perform a function means that the component has a capability to perform the function, and does not require the function to be actually performed by the component, unless noted otherwise.

As used herein, the term “determine” or “determining” can encompass one or more of a wide variety of actions. For example, “determining” can include one or more of calculating, computing, processing, deriving, detecting, estimating, investigating, looking up, inferring, ascertaining, measuring, resolving, selecting, choosing, obtaining, identifying, interpreting, demodulating, decoding, reading, establishing, forming or generating, among other examples. In some such examples, determining can involve a processor performing some type of calculating, computing, deriving, estimating, inferring, ascertaining, resolving, predicting or other processing to obtain one or more numerical values, sets, elements or other information or results. In some other such examples, determining can involve a processor identifying, looking up, investigating or otherwise obtaining some type of value, set, element or other information or result from a table, a data structure, a database or other memory device or location. In some other such examples, determining can involve a processor identifying, interpreting, demodulating, decoding, detecting, reading or otherwise obtaining some type of value, set, element or other information or result signaled in, for example, a received wireless packet. In some other such examples, determining can involve a processor selecting or choosing one or more values, sets, elements or other information or results from a larger set of values, sets elements or other information or results. In some other such examples, determining can involve a processor performing a measurement, such as on a received signal.

As used herein, the articles “a” and “an” are intended to refer to one or more items and may be used interchangeably with “one or more” or “at least one.” As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Additionally, as used herein, a “set” can refer to one or more items, and a “subset” can refer to a whole set or less than the whole set, but not an empty set. “Set,” “group,” and similar terms are intended to include one or more items and may be used interchangeably with “one or more.” Furthermore, as used herein, the term “or” is intended to be interpreted in the inclusive sense (such as when referring to a series) and may be used interchangeably with “and/or,” unless otherwise explicitly indicated (for example, if used in conjunction with “either” or “only one of”). For example, “A or B” may include A only, B only, or a combination of A and B. Also, as used herein, the terms “has,” “have,” “having,” “comprise,” “comprising,” “include” and “including,” and derivatives thereof or similar terms are intended to be open-ended terms that do not limit an element that they modify (for example, an element “having” A also may have B).

As used herein, the phrase “associated with” is intended to be interpreted in the inclusive sense, unless otherwise explicitly indicated. For example, the phrase “associated with” is not to be construed as a reference to a closed set of conditions, factors, criteria, elements, components, or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components, or actions, among other examples.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the scope of all aspects described herein. M any of these features may be combined in ways not specifically recited in the claims or disclosed in the specification. The disclosure of various aspects includes each dependent claim in combination with every other claim in the claim set.

What is claimed is:

1. A user equipment (UE), comprising:
a processing system that includes one or more processors and one or more code-storing memories coupled with the one or more processors, the processing system configured to cause the UE to:
receive, from a network node, a first message in accordance with a polar coding scheme;
transmit, to the network node, an indication of one or more frozen bits associated with the polar coding scheme, wherein the one or more frozen bits are selected in accordance with the first message; and
receive, from the network node, a second message in accordance with the one or more frozen bits.

2. The UE of claim 1, wherein the processing system is configured to cause the UE to:
transmit, to the network node, an indication of a capability associated with support for estimation of frozen bits and communications using estimated frozen bits.

3. The UE of claim 1, wherein the processing system is configured to cause the UE to:
transmit, to the network node, an indication of a plurality of bit indexes that correspond to a plurality of bits, wherein the plurality of bits includes the one or more frozen bits and one or more non-frozen bits.

4. The UE of claim 1, wherein the processing system is configured to cause the UE to:
transmit, to the network node, an indication of a first set of one or more bits to freeze, a second set of one or more bits to unfreeze, or a combination thereof, for the polar coding scheme.

5. The UE of claim 4, wherein a rate change is requested for the polar coding scheme in accordance with a first quantity of the first set of one or more bits different from a second quantity of the second set of one or more bits.

6. The UE of claim 1, wherein the one or more frozen bits are selected in accordance with one or more bit error rates, one or more bit capacities, or both, that correspond to a set of code blocks associated with the first message.

7. The UE of claim 6, wherein the processing system is configured to cause the UE to:
transmit, to the network node, an indication of the one or more bit error rates, the one or more bit capacities, or both.

8. The UE of claim 6, wherein the one or more bit error rates, the one or more bit capacities, or both, are estimated in accordance with respective log-likelihood ratios obtained in accordance with a soft decoder output prior to a slicing of one or more bit locations of the soft decoder output, the one or more bit locations corresponding to the one or more frozen bits, one or more information bits, and wherein the respective log-likelihood ratios are obtained for the set of one or more code blocks.

9. The UE of claim 6, wherein the one or more bit error rates are estimated in accordance with a subset of the set of one or more code blocks for which a cyclic redundancy check was successful.

10. The UE of claim 1, wherein the processing system is configured to cause the UE to:
receive, from the network node, an indication of one or more updated frozen bits associated with downlink communications in accordance with the indication of the one or more frozen bits; and
receive, from the network node, a third message in accordance with the one or more updated frozen bits.

11. The UE of claim 1, wherein the processing system is configured to cause the UE to:
receive, from the network node, an indication of one or more additional frozen bits associated with uplink transmissions; and
transmit, to the network node, a third message in accordance with the one or more additional frozen bits.

12. A method of wireless communication performed by a user equipment (UE), comprising:
receiving, from a network node, a first message in accordance with a polar coding scheme;
transmitting, to the network node, an indication of one or more frozen bits associated with the polar coding scheme, wherein the one or more frozen bits are selected in accordance with the first message; and
receiving, from the network node, a second message in accordance with the one or more frozen bits.

13. The method of claim 12, further comprising:
transmitting, to the network node, an indication of a capability associated with support for estimation of frozen bits and communications using estimated frozen bits.

14. The method of claim 12, further comprising:
transmitting, to the network node, an indication of a plurality of bit indexes corresponding to a plurality of bits, wherein the plurality of bits includes the one or more frozen bits and one or more non-frozen bits.

15. The method of claim 12, further comprising:
transmitting, to the network node, an indication of a first set of one or more bits to freeze, a second set of one or more bits to unfreeze, or a combination thereof, for the polar coding scheme.

16. The method of claim 15, wherein a rate change is requested for the polar coding scheme in accordance with a first quantity of the first set of one or more bits being different from a second quantity of the second set of one or more bits.

17. The method of claim 12, wherein the one or more frozen bits are selected in accordance with one or more bit error rates, one or more bit capacities, or both, corresponding to a set of code blocks associated with the first message.

18. The method of claim 17, further comprising:
transmitting, to the network node, an indication of the one or more bit error rates, the one or more bit capacities, or both.

19. The method of claim 17, wherein the one or more bit error rates, the one or more bit capacities, or both, are estimated in accordance with respective log-likelihood ratios obtained in accordance with a soft decoder output prior to a slicing of one or more bit locations of the soft decoder output, the one or more bit locations corresponding to the one or more frozen bits, one or more information bits, or a combination thereof, and wherein the respective log-likelihood ratios are obtained for the set of one or more code blocks.

20. A non-transitory computer-readable medium storing a set of instructions for wireless communication, the set of instructions comprising:
one or more instructions that, when executed by one or more processors of a user equipment (UE), cause the UE to:
receive, from a network node, a first message in accordance with a polar coding scheme;
transmit, to the network node, an indication of one or more frozen bits associated with the polar coding scheme, wherein the one or more frozen bits are selected in accordance with the first message; and
receive, from the network node, a second message in accordance with the one or more frozen bits.
